(19) United States
(12) Patent Application Publication
(10) Pub. No.: US 2012/0080691 A1
(43) Pub. Date: Apr. 5, 2012

(54) LIGHT EMITTING DIODE AND MAKING METHOD THEREOF

(75) Inventors: TZU-CHIEN HUNG, Hukou Shiang (TW); CHIA-HUI SHEN, Hukou Shiang (TW)

(73) Assignee: ADVANCED OPTOELECTRONIC TECHNOLOGY, INC., Hsinchu Hsien (TW)

(21) Appl. No.: 13/151,255

(22) Filed: Jun. 1, 2011

(30) Foreign Application Priority Data
Sep. 30, 2010 (CN) 201010297708.X

(51) Int. Cl. H01L 33/08

(52) U.S. Cl. 257/88; 438/34; 257/E33.012

(57) ABSTRACT

An LED includes a substrate, a first P-type semiconductor layer formed on the substrate and a plurality of LED dies arranged on the first P-type semiconductor layer. The LED dies are electrically connected to each other in series. The present invention also relates to a method for making such an LED.

### BACKGROUND

1. Technical Field

The present disclosure relates to solid state light emitting devices and, more particularly, to a light emitting diode (LED).

2. Description of Related Art

Nowadays, LEDs have the advantages of low-power consumption and long life-span, etc, and thus are widely used for display, backlight, indoor/outdoor illumination, automobile illumination, etc.

An LED usually includes a substrate, a buffer layer arranged on the substrate, and a semiconductor epitaxial layer arranged on the buffer layer. Etching the semiconductor epitaxial layer to form a plurality of spaced LED chips which are isolated from each other, it need to etch the buffer layer and the substrate, and this process is time consuming and laborious.

Therefore, it is desirable to provide an LED and making method thereof which can overcome the above-mentioned shortcomings.

### BRIEF DESCRIPTION OF THE DRAWINGS

FIG. 1 is a cross-sectional view of an embodiment of an LED of the present disclosure.

FIG. 2 to FIG. 9 are cross-sectional views showing different steps of an embodiment of a method for manufacturing the LED of FIG. 1.

### DETAILED DESCRIPTION

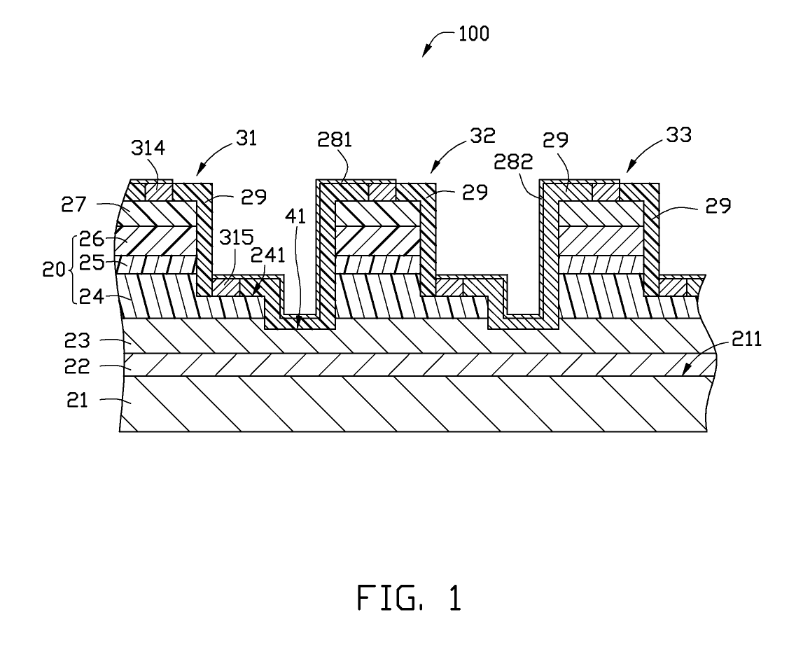

Referring to FIG. 1, an LED 100 in accordance with an embodiment of the present disclosure is disclosed. The LED 100 includes a substrate 21, a buffer layer 22 formed on the substrate 21, a first P-type semiconductor layer 23 formed on the buffer layer 22, and a plurality of spaced LED chips arranged on the first P-type semiconductor layer 23 in an array. In the present embodiment, three LED chips, i.e., a first LED chip 31, a second LED chip 32 and a third LED chip 33, are shown. Each of the first, the second and the third LED chips 31, 32 and 33 includes an LED die 20.

The substrate 21 preferably is a single crystal plate and can be made of a material of sapphire, silicon carbide (SiC), silicon (Si), gallium arsenide (GaAs), lithium aluminate (LiAlO₂), magnesium oxide (MgO), zinc oxide (ZnO), GaN, aluminum nitride (AlN) or indium nitride (InN), etc. In the present embodiment, the substrate 21 is made of silicon, and has an upper surface 211.

The buffer layer 22 is formed on the upper surface 211 of the substrate 21. In the present embodiment, the buffer layer 22 is an N-type nitride semiconductor layer, such as GaN layer, or AlₓGa₍₁₋ₓ₎N (0<x<0.2) layer. The buffer layer 22 is used to reduce the lattice mismatch between the substrate 21 and the LED dies 20.

The first P-type semiconductor layer 23 is formed on a top surface of the buffer layer 22. In the present embodiment, the first P-type semiconductor layer 23 is a P-type semiconductor layer, such as a P-type GaN layer. A thickness of the first P-type semiconductor layer 23 is less than 1.5 μm.

The first, the second and the third LED chips 31, 32 and 33 are separately arranged on the first P-type semiconductor layer 23, and electrically insulated from each other. In the present embodiment, the first P-type semiconductor layer 23 defines a groove 41 between each two neighboring LED chips 31, 32, 33 A depth of the groove 41 is less than a thickness of the first P-type semiconductor layer 23. That is, the groove 41 does not extend through the first P-type semiconductor layer 23.

Each of the LED dies 20 includes an N-type semiconductor layer 24, an active layer 25, and a second P-type semiconductor layer 26 epitaxially formed on the first P-type semiconductor layer 23 in sequence. In the present embodiment, the N-type semiconductor layer 24 is N-type AlₓGa₍₁₋ₓ₎N (0<x<0.2), and the second P-type semiconductor layer 26 is P-type AlₓGa₍₁₋ₓ₎N (0<x<0.2). Each LED die 20 has a mesa pattern, and a portion of the N-type semiconductor layer 24 is exposed to form an exposed surface 241.

In the present embodiment, each LED chip 31, 32, 33 further includes a P-type transparent electrode layer 27 formed on a top surface of the second P-type semiconductor layer 26 of the LED die 20. The P-type transparent electrode layer 27 is an indium tin oxide (ITO) layer, and is used for diffusing current, and improving the light extraction efficiency.

A first P-type electrode 314 is formed on a middle portion of a top surface of the P-type transparent electrode layer 27 of each LED chip 31, 32, 33. A first N-type electrode 315 is formed on a portion of the exposed surface 241 of the N-type semiconductor layer 24 of each LED chip 31, 32, 33.

An insulating protection layer 29 covers the other portion of the top surface of the P-type transparent electrode layer 27 and the other portion of the exposed surface 241 of each first, the second and the third LED chip 31, 32 and 33 without the N-type and P-type electrodes 315, 314; therefore, the N-type electrodes 315 and the P-type electrodes 314 are electrically isolated from each other. In this embodiment, the insulating protection layer 29 further extends into the groove 41 and covers an exposed area of the first P-type semiconductor layer 23 between each two of the LED chips 31, 32, 33.

The first, the second and the third LED chips 31, 32 and 33 connect to each other in series by electrically conductive traces made of metal such as gold. In the present embodiment, the first N-type electrode 315 of the first LED chip 31 is electrically connected to the second P-type electrode 314 of the second LED chip 32 by a conductive trace 281, and the second N-type electrode 315 of the second LED chip 32 is electrically connected to the second P-type electrode 314 of the third LED chip 33 by a conductive trace 282. In the present embodiment, the conductive traces 281, 282 are arranged on a top surface of the protection layers 29.

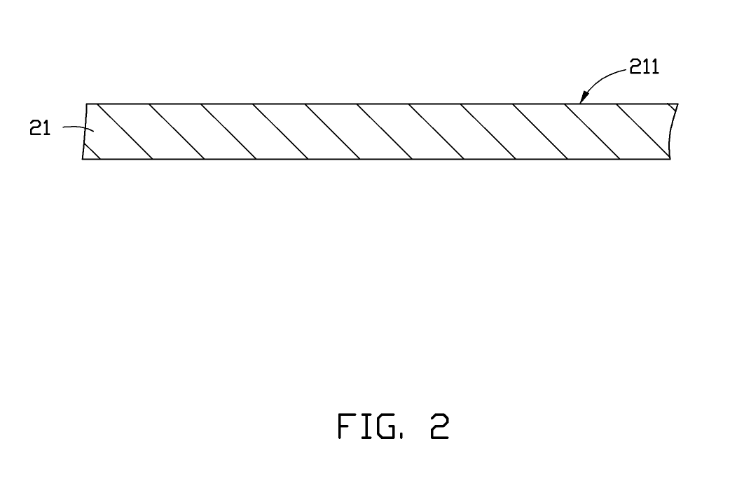

Referring to FIGS. 2 to 10, a method for manufacturing the LED 100 in accordance with an exemplary embodiment is also disclosed, which includes the following steps.

Referring to FIG. 2, the first step is to provide a substrate 21. In the present embodiment, the substrate 21 is a single plate made of silicon. The substrate 21 includes a planar upper surface 211.

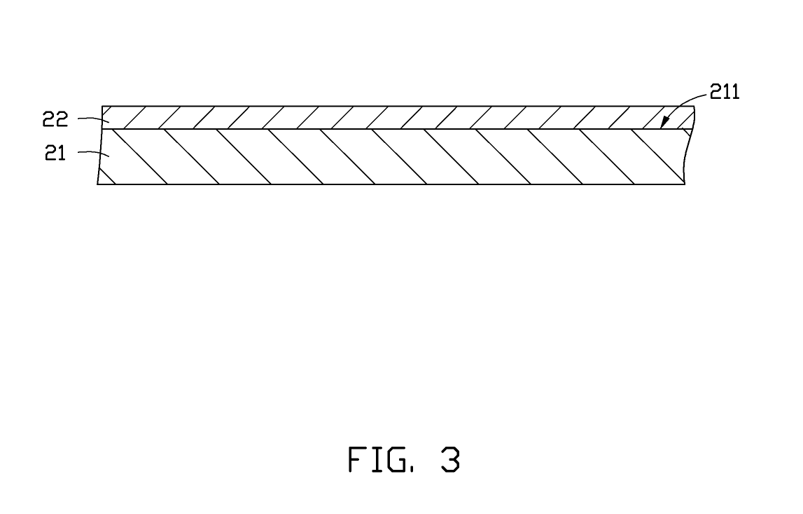

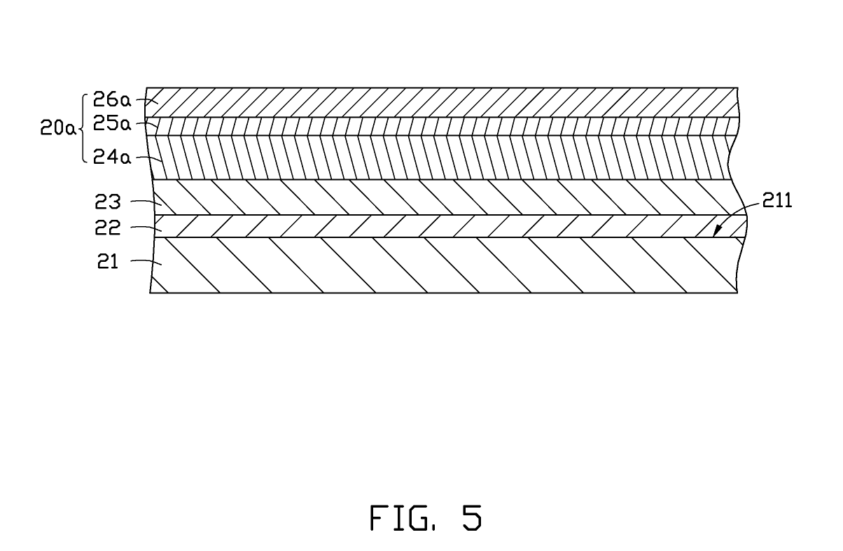

Referring to FIG. 3, the second step is to form a buffer layer 22 on the first surface 211 of the substrate 21. In the present embodiment, the buffer layer 22 is an N-type nitride semiconductor layer, such as an N-type GaN layer. The buffer layer 22 is used to reduce the lattice mismatch between the substrate 21 and a semiconductor epitaxial layer 20a (FIG. 5) formed on the buffer layer 22.

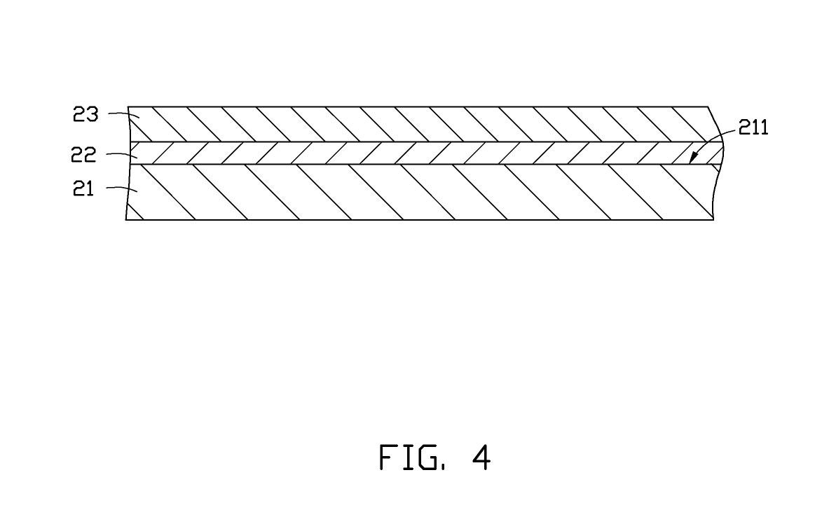

Referring to FIG. 4, the third step is to form a first P-type semiconductor layer 23 on a top surface of the buffer layer 22. In the present embodiment, the first P-type semiconductor layer 23 is a P-type semiconductor layer, such as a P-type GaN layer. A thickness of the first P-type semiconductor layer 23 is less than 1.5 μm.

Referring to FIG. 5, the fourth step is to epitaxially grow the semiconductor epitaxial layer 20a on the first P-type semiconductor layer 23. In the present embodiment, the semiconductor epitaxial layer 20a includes an N-type semiconductor layer 24a, an active layer 25a, and a second P-type semiconductor layer 26a epitaxially formed on the first P-type semiconductor layer 23 in a sequence.

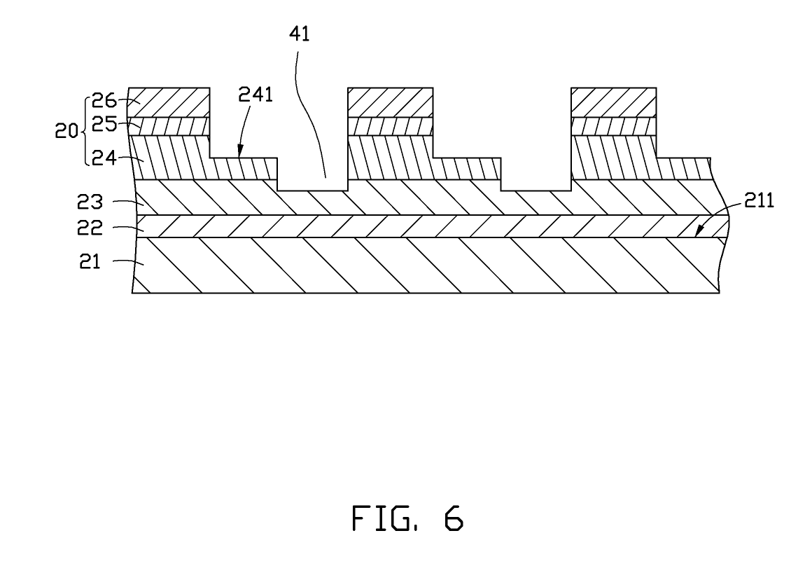

Referring to FIG. 6, the fifth step is to etch the semiconductor epitaxial layer 20a to form an array of spaced LED dies 20 (only three LED dies 20 are shown) on the first P-type semiconductor layer 23, wherein each LED die 20 includes an N-type semiconductor layer 24, an active layer 25 and a second P-type semiconductor layer 26. Each LED die 20 is etched to form a mesa pattern, and a portion of the N-type semiconductor layer 24 is exposed to form an exposed surface 241 thereon. Because of the provision of the first P-type semiconductor layer 23, the etching can be limited in the semiconductor epitaxial layer 20a, and the etching of the buffer layer 22 and the substrate 21 which is required by the conventional method is not necessary in the present disclosure. Furthermore, a groove 41 is defined in the first P-type semiconductor layer 23 between the LED dies 20 for enhancing electrical insulation between the LED dies 20.

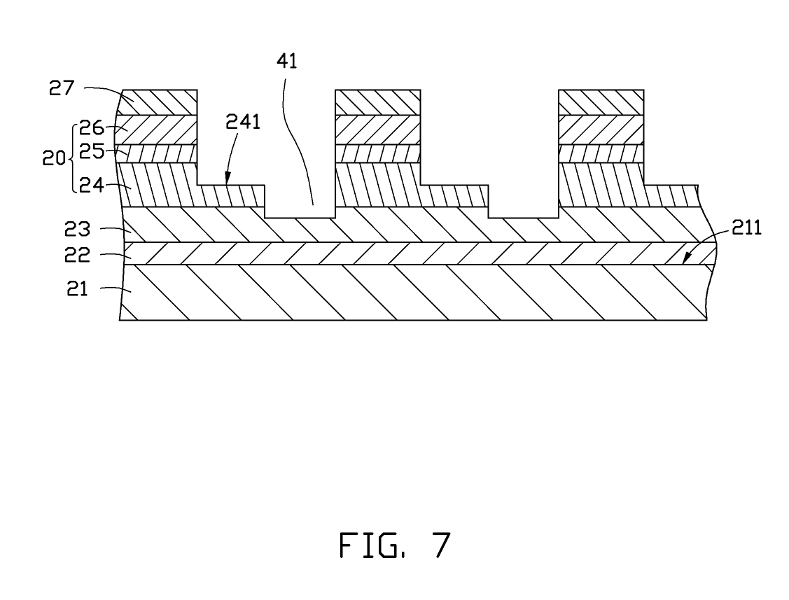

Referring to FIG. 7, the sixth step is to form a P-type transparent electrode layer 27 on a top surface of the second P-type semiconductor layer 26 of each LED die 20. The P-type transparent electrode layer 27 is an indium tin oxide (ITO) layer, and is used for diffusing current, and improving the light extraction efficiency.

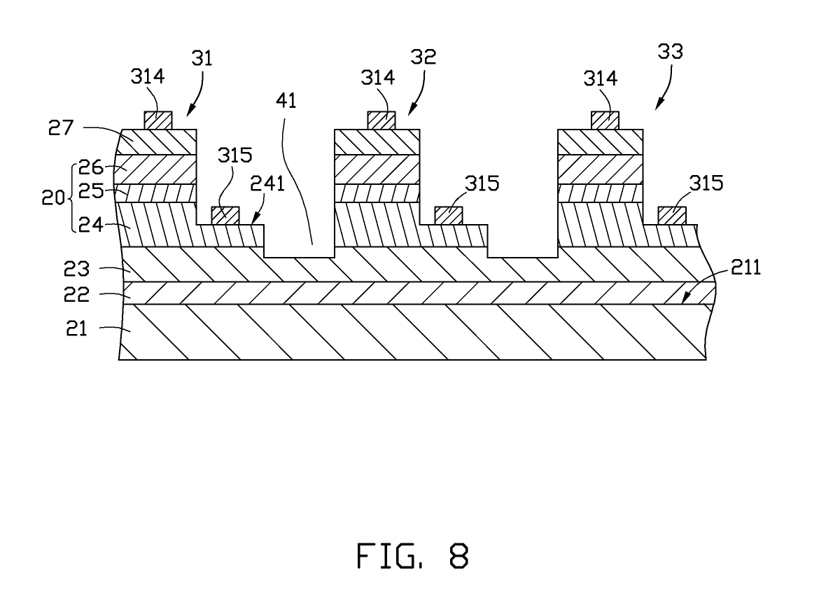

Referring to FIG. 8, the seven step is to form P-type electrodes 314 and N-type electrodes 315 on the LED dies 20. In the present embodiment, each P-type transparent electrode layer 27 has one P-type electrode 314 formed thereon, and the exposed surface 241 of each LED die 20 has one N-type electrode 315 formed thereon. Each LED die 20 and the corresponding P-type transparent electrode layer 27, first P-type electrode 314 and first N-type electrode 315 formed thereon together construct an LED chip. The three LED dies 20 respectively form three LED chips 31, 32, 33.

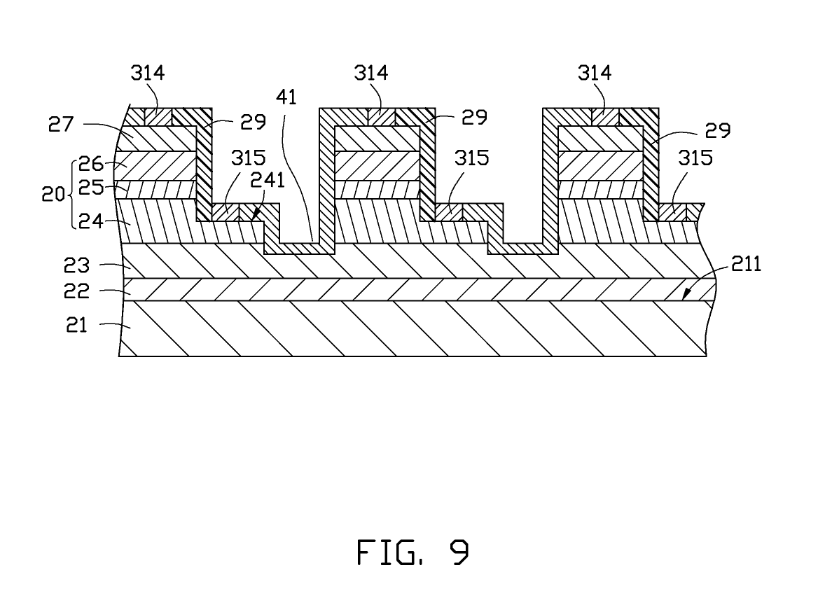

Referring to FIG. 9, the eighth step is to form an insulating protection layer 29 between the N-type electrode 314 and P-type electrode 315 of each LED chip 31, 32, 33.

Referring to FIG. 1 again, the ninth step is to electrically connect first, the second and the third LED chips 31, 32 and 33 in series by electrically conductive traces which are made of metal, such as gold. In the present embodiment, the N-type electrode 315 of the first LED chip 31 is electrically connected to the P-type electrode 314 of the second LED chip 32 by a conductive trace 281, and the N-type electrode 315 of the second LED chip 32 is electrically connected to the P-type electrode 314 of the third LED chip 33 by a conductive trace 282.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED, comprising:
a substrate;
a first P-type semiconductor layer formed on the substrate; and
a plurality of LED dies arranged on the first P-type semiconductor layer, the LED dies being electrically connected to each other in series.

2. The LED of claim 1, further comprising a buffer layer arranged between the substrate and the first P-type semiconductor layer.

3. The LED of claim 1, wherein a thickness of the first P-type semiconductor layer is less than 1.5 μm.

4. The LED of claim 1, wherein the first P-type semiconductor layer is a P-type GaN layer.

5. The LED of claim 1, wherein each LED die comprises an N-type semiconductor layer, an active layer and a second P-type semiconductor layer formed on the first P-type semiconductor layer in a sequence, each LED die having a mesa pattern, and a portion of the N-type semiconductor layer being exposed.

6. The LED of claim 5, wherein a P-type electrode is formed on a top surface of the P-type semiconductor layer, and an N-type electrode is formed on the exposed portion of the N-type semiconductor layer.

7. The LED of claim 6, wherein the P-type electrode of one LED die is electrically connected the N-type electrode of an adjacent LED die.

8. The LED of claim 6, wherein an indium tin oxide is formed between the P-type electrode and the P-type semiconductor layer.

9. The LED of claim 6, further comprising an insulating protection layer arranged between the N-type and P-type electrodes of each of the LED dies.

10. The LED of claim 1, wherein a plurality of grooves is defined in the first P-type semiconductor layer between the LED dies.

11. A method for manufacturing an LED comprising:
providing a substrate;
forming a first P-type semiconductor layer on the substrate;
growing a semiconductor epitaxial layer on the first P-type semiconductor layer, the semiconductor epitaxial layer comprising an N-type semiconductor layer, an active layer and a second P-type semiconductor layer;
etching the semiconductor epitaxial layer to form a plurality of spaced LED dies on the first P-type semiconductor layer, and a portion of the N-type semiconductor layer of each of the LED die being exposed;
forming a P-type electrode and an N-type electrode for each of the LED die; and
connecting the LED dies electrically.

12. The method for manufacturing an LED of claim 11, further comprising forming an insulating protection layer between the N-type and P-type electrodes of each of the LED dies, and then electrically connecting the LED dies in series by forming a conductive trace electrically connecting the N-type electrode of one LED die and the P-type electrode of an adjacent LED die.

13. The method for manufacturing an LED of claim 11, further comprising forming an indium tin oxide on the P-type semiconductor layer, and then forming the P-type electrode and the N-type electrode for each of the LED dies.

14. The method for manufacturing an LED of claim 11, wherein a thickness of the first P-type semiconductor layer is less than 1.5 μm.

15. The method for manufacturing an LED of claim 11, wherein the first P-type semiconductor layer is a P-type GaN layer.
